(19) United States
(12) Patent Application Publication
(10) Pub. No.: US 2025/0113594 A1
(43) Pub. Date: Apr. 3, 2025

(54) SEMICONDUCTOR INTEGRATED CIRCUIT DEVICE

(71) Applicant: Socionext Inc., Kanagawa (JP)

(72) Inventor: Hideyuki KOMURO, Yokohama-shi (JP)

(21) Appl. No.: 18/972,119

(22) Filed: Dec. 6, 2024

Related U.S. Application Data
(63) Continuation of application No. PCT/JP2023/020840, filed on Jun. 5, 2023.

(30) Foreign Application Priority Data
Jun. 20, 2022 (JP) 2022-098783

(51) Int. Cl. H10D 84/83; H01L 23/528; H10D 30/00

(52) U.S. Cl. CPC H10D 84/832; H01L 23/5286; H10D 30/501

(57) ABSTRACT

A semiconductor integrated circuit device includes a plurality of standard cells each having a nanosheet field effect transistor (FET). A first standard cell includes a first buried power rail extending in the X direction and a nanosheet FET having a first nanosheet extending in the X direction. A second standard cell includes a second buried power rail greater in size in the Y direction than the first buried power rail and a nanosheet FET having a second nanosheet greater in size in the Y direction than the first nanosheet.

### CROSS-REFERENCE TO RELATED APPLICATIONS

This is a continuation of International Application No. PCT/JP2023/020840 filed on Jun. 5, 2023, which claims priority to Japanese Patent Application No. 2022-098783 filed on Jun. 20, 2022. The entire disclosures of these applications are incorporated by reference herein.

### BACKGROUND

The present disclosure relates to a semiconductor integrated circuit device including standard cells.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, thereby designing an LSI chip.

For higher integration of a semiconductor integrated circuit, it is proposed to use, for standard cells, buried power rails (BPRs) that are power supply lines laid in a buried interconnect layer, not power supply lines laid in a metal interconnect layer formed above transistors as conventionally done.

U.S. Patent Application Publication No. 2019/0080969 (FIG. 1E) (Patent Document 1) discloses a configuration of a block constituted by standard cells, in which power supply lines are constituted by buried power rails, and the buried power rails are connected to sources of transistors and further connected to power supply lines laid in an upper interconnect layer.

U.S. Patent Application Publication No. 2020/0105752 (FIG. 3) (Patent Document 2) discloses a semiconductor integrated circuit device including standard cells in which nanosheets of gate all around (GAA) nanosheet transistors have different widths from one another

Since buried power rails are buried in a substrate, a well, or a shallow trench isolation (STI), it is not allowed to form them in regions where sources, drains, and channels of transistors are present. On the other hand, buried power rails are required to have the capability of supplying a sufficient current to transistors. Also, in microfabrication processes, there are cases of imposing restrictions on interconnect layers formed above transistors, such as keeping constant the extension direction of interconnects, the width of interconnects, and the spacing between interconnects, for the purposes of preventing variations, improving manufacturing easiness, and improving yield, and these restrictions must be observed.

An objective of the present disclosure is presenting a configuration of a semiconductor integrated circuit device using buried power rails, in which, while the regularity of arrangement of interconnects in an interconnect layer located above transistors is maintained, each standard cell can be provided with a sufficient current supply capability responsive to its power consumption.

### SUMMARY

According to one mode of the present disclosure, in a semiconductor integrated circuit device including a plurality of standard cells each having a nanosheet field effect transistor (FET), in a first interconnect layer located above the nanosheet FETs, metal interconnects extend in a first direction and are placed on virtual grid lines spaced at an equal pitch in a second direction perpendicular to the first direction, the plurality of standard cells includes a first standard cell having a cell height corresponding to (0.5×N1) (N1 is a natural number) times the pitch of the virtual grid lines, and a second standard cell having a cell height corresponding to (0.5×N2) (N2 is a natural number, N2>N1) times the pitch of the virtual grid lines, the first standard cell includes a first buried power rail extending in the first direction, and a first nanosheet FET having a first nanosheet extending in the first direction, and the second standard cell includes a second buried power rail extending in the first direction and having a size in the second direction greater than the first buried power rail, and a second nanosheet FET having a second nanosheet extending in the first direction and having a size in the second direction greater than the first nanosheet.

According to the above mode, the semiconductor integrated circuit device includes a plurality of standard cells each having a nanosheet FET. In a first interconnect layer located above the nanosheet FETs, interconnects extend in a first direction and are placed on virtual grid lines spaced at an equal pitch in a second direction perpendicular to the first direction. The first standard cell, having a cell height corresponding to (0.5×N1) (N1 is a natural number) times the pitch of the virtual grid lines, includes a first buried power rail and a first nanosheet FET having a first nanosheet. The second standard cell, having a cell height corresponding to (0.5×N2) (N2 is a natural number, N2>N1) times the pitch of the virtual grid lines, includes a second nanosheet FET having a second nanosheet greater in size in the second direction than the first nanosheet and a second buried power rail. The second buried power rail is greater in size in the second direction than the first buried power rail. That is, the second standard cell including the nanosheet FET greater in transistor size includes the buried power rail greater in line width. Therefore, the first and second standard cells can be provided with sufficient current supply capabilities responsive to their power consumption. Also, since the power supply lines having different line widths are buried power rails, the regularity of arrangement of interconnects in the first interconnect layer located above the nanosheet FETs is not disturbed.

According to another mode of the present disclosure, in a semiconductor integrated circuit device including a plurality of standard cells each having a nanosheet field effect transistor (FET), the plurality of standard cells includes a first standard cell and a second standard cell, the first standard cell includes a first buried power rail extending in a first direction, and a first nanosheet FET having a first nanosheet extending in the first direction, and the second standard cell includes a second buried power rail extending in the first direction and having a size in a second direction greater than the first buried power rail, the second direction being perpendicular to the first direction, and a second nanosheet FET having a second nanosheet extending in the first direction and having a size in the second direction greater than the first nanosheet.

According to the above mode, the semiconductor integrated circuit device includes a plurality of standard cells each having a nanosheet FET. The first standard cell includes a first buried power rail and a first nanosheet FET having a first nanosheet. The second standard cell includes a second nanosheet FET having a second nanosheet greater in size in the second direction than the first nanosheet and a second buried power rail. The second buried power rail is greater in size in the second direction than the first buried power rail. That is, the second standard cell including the nanosheet FET greater in transistor size includes the buried power rail greater in line width. Therefore, the first and second standard cells can be provided with sufficient current supply capabilities responsive to their power consumption. Also, since the power supply lines having different line widths are buried power rails, the regularity of arrangement of interconnects in an interconnect layer located above the nanosheets is not disturbed.

According to the present disclosure, in a semiconductor integrated circuit device using buried power rails, while the regularity of arrangement of interconnects in an interconnect layer located above transistors is maintained, each standard cell can be provided with a sufficient current supply capability responsive to its power consumption.

### BRIEF DESCRIPTION OF THE DRAWINGS

FIGS. 1A and 1B are plan views showing layout structures of inverter cells constituting a semiconductor integrated circuit device according to an embodiment.

FIG. 2 is a plan view showing a layout structure of an inverter cell constituting the semiconductor integrated circuit device according to the embodiment.

FIGS. 3A and 3B show cross-sectional structures of the inverter cell shown in FIG. 1A.

FIGS. 4A and 4B are plan views showing layout structures of 2-input NAND cells constituting the semiconductor integrated circuit device according to the embodiment.

FIG. 5 is a plan view showing a layout structure of a 2-input NAND cell constituting the semiconductor integrated circuit device according to the embodiment.

FIG. 6A is a circuit diagram of an inverter cell, and FIG. 6B is a circuit diagram of a 2-input NAND cell.

FIG. 7 shows a configuration example of circuit blocks of the semiconductor integrated circuit device according to the embodiment.

FIGS. 8A to 8C are plan views showing layout structures of inverter cells constituting a semiconductor integrated circuit device according to an alteration.

FIGS. 9A and 9B are plan views showing layout structures of 2-input NAND cells constituting the semiconductor integrated circuit device according to the alteration.

FIG. 10 is a plan view showing a layout structure of a 2-input NAND cell constituting the semiconductor integrated circuit device according to the alteration.

FIG. 11 shows a configuration example of circuit blocks of the semiconductor integrated circuit device according to the alteration.

### DETAILED DESCRIPTION

An embodiment of the present disclosure will be described hereinafter with reference to the accompanying drawings. In the following embodiment, a semiconductor integrated circuit device includes a plurality of standard cells (hereinafter simply called cells as appropriate), and at least some of the standard cells include nanosheet field effect transistors (FETs).

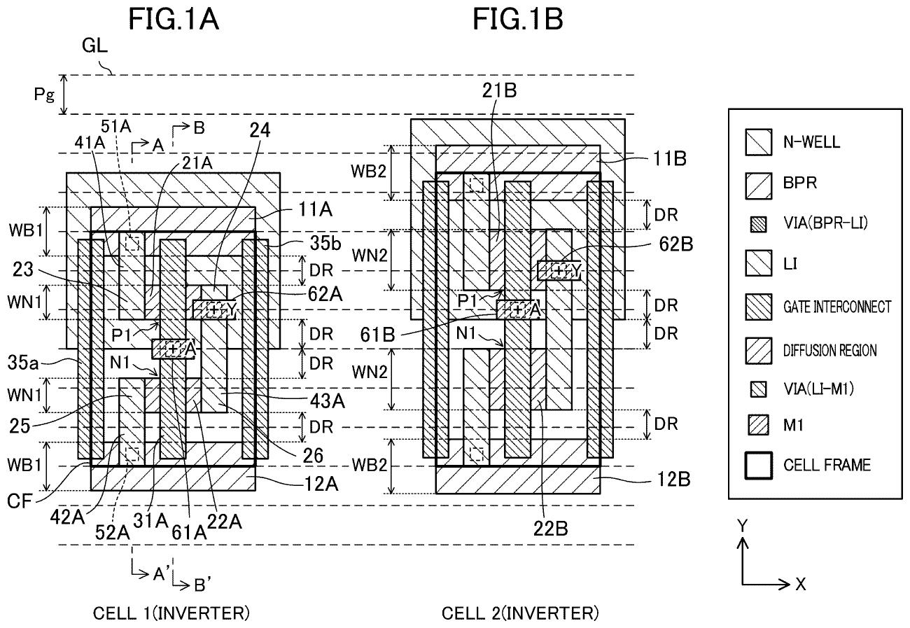

In the present disclosure, “VDD” and “VSS” indicate power supply voltages or power supplies themselves. Also, hereinafter, in the plan views such as FIGS. 1A-1B, the horizontal direction in the figure is called an X direction (corresponding to the first direction), the vertical direction in the figure is called a Y direction (corresponding to the second direction), and the direction perpendicular to the substrate plane is called a Z direction.

### First Embodiment

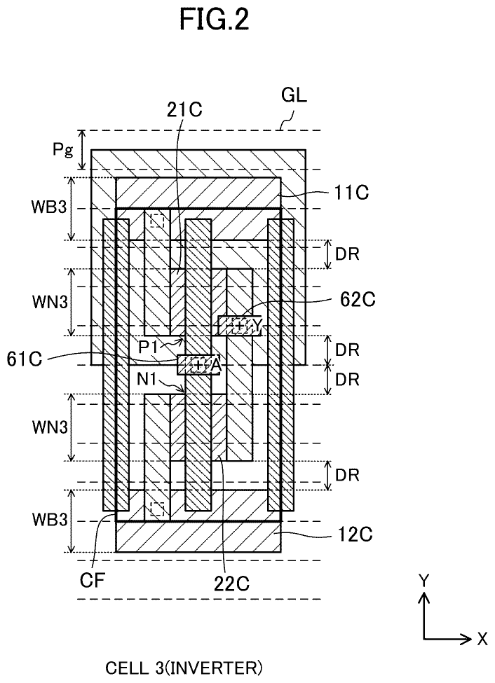

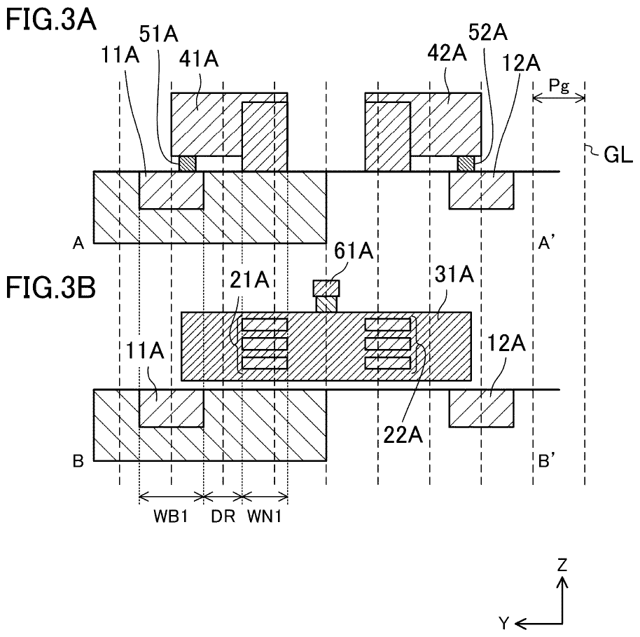

FIGS. 1A, 1B, and 2 are plan views showing layout structure examples of standard cells constituting a semiconductor integrated circuit device according to this embodiment. These standard cells are all inverter cells. FIGS. 3A and 3B are views showing cross-sectional structures of the cell shown in FIG. 1A, where FIG. 3A is a cross-sectional view taken along line A-A′ of FIG. 1A, and FIG. 3B is a cross-sectional view taken along line B-B′ of FIG. 1A.

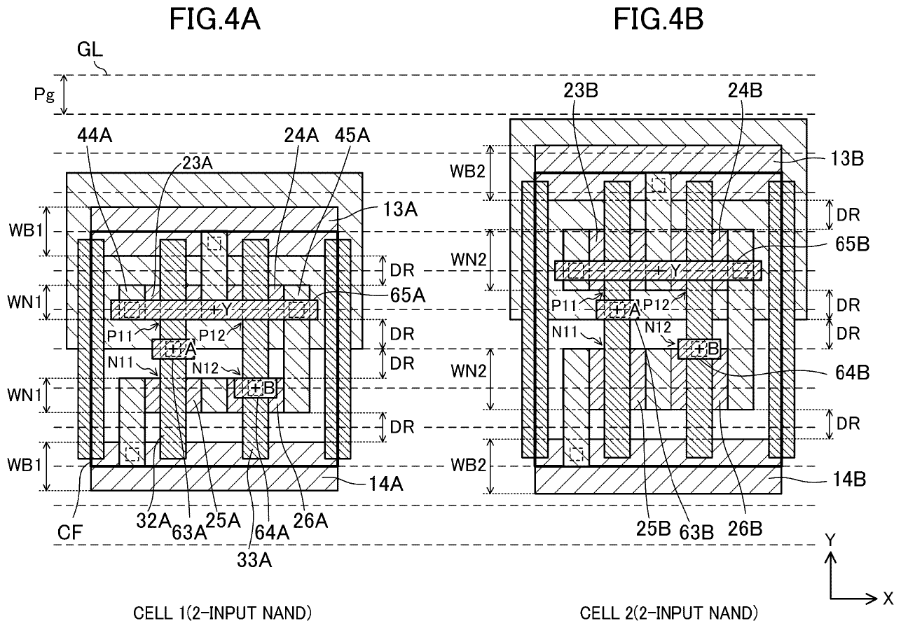

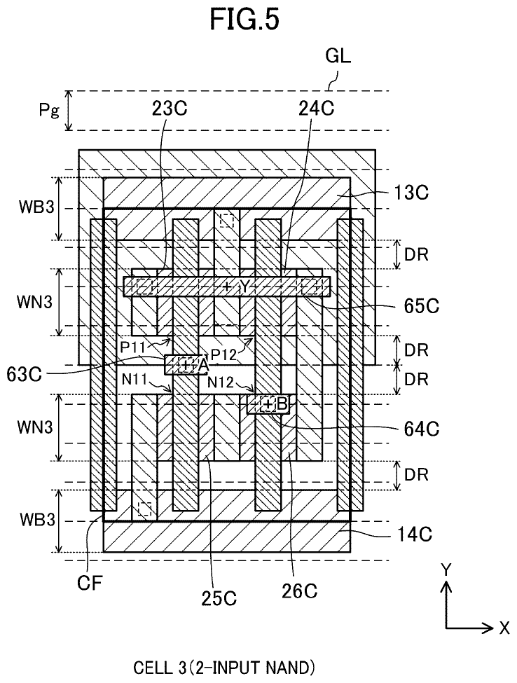

FIGS. 4A, 4B, and 5 are plan views showing layout structure examples of other standard cells constituting the semiconductor integrated circuit device of this embodiment. These standard cells are all 2-input NAND cells.

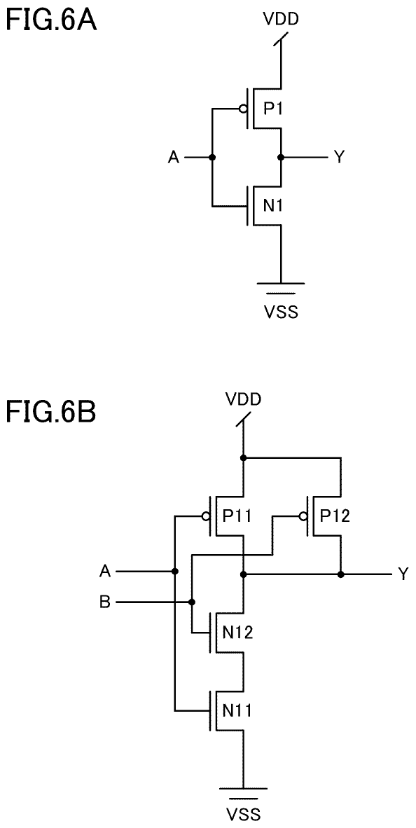

FIGS. 6A and 6B show circuit diagrams of cells, where FIG. 6A is a circuit diagram of the inverter cells shown in FIGS. 1A, 1B, and 2, and FIG. 6B is a circuit diagram of the 2-input NAND cells shown in FIGS. 4A, 4B, and 5.

The inverter cells shown in FIGS. 1A, 1B, and 2 and the 2-input NAND cells shown in FIGS. 4A, 4B, and 5 have nanosheet FETs. In this embodiment, a nanosheet FET has a set of three nanosheets that are arranged in the Z direction and extend in the X direction. Note that the nanosheet FET may otherwise have a single nanosheet, or a set of two or four or more nanosheets arranged in the Z direction.

In a first metal interconnect layer (M1 interconnect layer), metal interconnects extend in the X direction and are placed on virtual grid lines GL (shown by the thin broken lines in the figure) spaced at equal intervals in the Y direction. The pitch of the virtual grid lines GL is Pg. That is, the M1 interconnects are arranged at the pitch Pg. The pitch Pg is 24 nm, for example. The M1 interconnect layer corresponds to the first interconnect layer located above nanosheet FETs.

The size of each cell in the Y direction, i.e., the cell height, is an integral multiple, or an (integer+0.5) multiple, of the pitch Pg of the virtual grid lines GL. In other words, the cell height of each cell is 0.5×N (N is a natural number) times the pitch Pg of the virtual grid lines GL.

Specifically, the cell height of the inverter cell shown in FIG. 1A and the 2-input NAND cell shown in FIG. 4A is six times the pitch Pg (cell height=Pg×6). When the cell height is expressed as (0.5×N1 (N1 is a natural number)) times the pitch Pg, N1=12. When the pitch Pg is 24 nm, the cell height is 144 nm. The cell height of the inverter cell shown in FIG. 1B and the 2-input NAND cell shown in FIG. 4B is 7.5 times the pitch Pg (cell height=Pg×7.5). When the cell height is expressed as (0.5×N2 (N2 is a natural number)) times the pitch Pg, N2=15. When the pitch Pg is 24 nm, the cell height is 180 nm. The cell height of the inverter cell shown in FIG. 2 and the 2-input NAND cell shown in FIG. 5 is eight times the pitch Pg (cell height=Pg×8). When the cell height is expressed as (0.5×N3 (N3 is a natural number)) times the pitch Pg, N3=16. When the pitch Pg is 24 nm, the cell height is 192 nm. Here, N1<N2<N3.

The layout structures of the inverter cells shown in FIGS. 1A-1B, 2, and 3A-3B will be described.

The inverter cell (cell 1) shown in FIG. 1A has a cell height six times the pitch Pg of the virtual grid lines GL as described above. The cell 1 is placed so that the upper and lower sides of the cell frame (CF) match with the positions of virtual grid lines GL. Power supply lines 11A and 12A extend in the X direction along both ends of the cell 1 in the Y direction. The power supply lines 11A and 12A are both buried power rails (BPRs) formed in a buried interconnect layer. The power supply line 11A supplies the power supply voltage VDD, and the power supply line 12A supplies the power supply voltage VSS. The center positions of the power supply lines 11A and 12A in the Y direction match with the upper and lower sides, respectively, of the cell frame CF, i.e., match with virtual grid lines GL. The width, i.e., the size in the Y direction, of the power supply lines 11A and 12A is WB1, which is 28 nm, for example.

The power supply line 11A is shared with a standard cell adjacent to the cell 1 on the upper side in the figure, and the power supply line 12A is shared with a standard cell adjacent to the cell 1 on the lower side in the figure.

A p-type transistor P1 is formed on an N-well, and an n-type transistor N1 is formed on a P-well or a p-type substrate. The transistors P1 and N1 are arranged side by side in the Y direction. The transistors P1 and N1 have three nanosheets 21A and three nanosheets 22A, respectively, as channel regions. That is, the transistors P1 and N1 are nanosheet FETs. The width, i.e., the size in the Y direction, of the nanosheets 21A and 22A is WN1, which is 18 nm, for example. As described earlier, the number of nanosheets of each nanosheet FET is not limited to three. The regions of the nanosheets 21A and 22A are to be the channel regions of the transistors P1 and N1, respectively.

The power supply line 11A and the nanosheets 21A of the transistor P1 are placed apart from each other. Similarly, the power supply line 12A and the nanosheets 22A of the transistor N1 are placed apart from each other. In FIG. 1A, the power supply line 11A and the nanosheets 21A, and the power supply line 12A and the nanosheets 22A, are apart from each other by a distance DR that is the minimum distance required for manufacturing, which is 20 nm, for example.

The distance between the nanosheets 21A of the transistor P1 and the lower end of the N-well in the figure, and the distance between the nanosheets 22A of the transistor N1 and the lower end of the N-well in the figure, are also DR. Therefore, the distance between the nanosheets 21A of the transistor P1 and the nanosheets 22A of the transistor N1 is double the distance DR, which is 40 nm when the distance DR is 20 nm.

On the left and right sides of the nanosheets 21A in the figure, pads 23 and 24 each made of a semiconductor layer of an integral structure connected to the three sheets are respectively formed. The pad 23 is to be the source region of the transistor P1, and the pad 24 is to be the drain region of the transistor P1. On the left and right sides of the nanosheets 22A in the figure, pads 25 and 26 each made of a semiconductor layer of an integral structure connected to the three sheets are respectively formed. The pad 25 is to be the source region of the transistor N1, and the pad 26 is to be the drain region of the transistor N1.

A gate interconnect 31A extending in the Y direction is formed. The gate interconnect 31A surrounds the peripheries of the nanosheets 21A of the transistor P1 and the nanosheets 22A of the transistor N1 in the Y and Z directions through gate insulating films (not shown). The gate interconnect 31A corresponds to the gates of the transistors P1 and N1. Also, dummy gate interconnects 35a and 35b are formed on the cell frame CF on both sides of the gate interconnect 31A in the X direction.

Local interconnects 41A, 42A, and 43A extending in the Y direction are formed in a local interconnect (LI) layer. The local interconnect 41A is connected to the pad 23 and also connected to the power supply line 11A through a via 51A. The local interconnect 42A is connected to the pad 25 and also connected to the power supply line 12A through a via 52A. The local interconnect 43A is connected to the pads 24 and 26.

In the M1 interconnect layer, M1 interconnects 61A and 62A extending in the X direction are formed. The M1 interconnect 61A, which corresponds to an input node A, is connected to the gate interconnect 31A through a contact. The M1 interconnect 62A, which corresponds to an output node Y, is connected to the local interconnect 43A through a contact. Both the M1 interconnects 61A and 62A are on virtual grid lines GL. The M1 interconnects 61A and 62A have the same line width as the other interconnects in the M1 interconnect layer.

The inverter cell (cell 2) shown in FIG. 1B has a cell height 7.5 times the pitch Pg of the virtual grid lines GL as described above. The cell 2 is placed so that one of the upper and lower sides of the cell frame CF matches with the position of a virtual grid line GL and the other matches with the position of the center between adjacent virtual grid lines GL. In the placement of FIG. 1B, the lower side of the cell frame CF matches with the position of a virtual grid line GL, and the upper side of the cell frame CF matches with the position of the center between adjacent virtual grid lines GL.

The cell 2 shown in FIG. 1B has a layout structure similar to that of the cell 1 of FIG. 1A, except for the followings. The width WB2 of power supply lines 11B and 12B that are buried power rails is greater than the width WB1 of the power supply lines 11A and 12A of the cell 1 (WB2>WB1). The width WB2 is 36 nm, for example. Also, the width WN2 of nanosheets 21B and 22B is greater than the width WN1 of the nanosheets 21A and 22A of the cell 1 (WN2>WN1). The width WN2 is 32 nm, for example.

The inverter cell (cell 3) shown in FIG. 2 has a cell height eight times the pitch Pg of the virtual grid lines GL as described above. The cell 3 is placed so that the upper and lower sides of the cell frame CF match with the positions of virtual grid lines GL.

The cell 3 shown in FIG. 2 has a layout structure similar to that of the cell 1 of FIG. 1A, except for the followings. The width WB3 of power supply lines 11C and 12C that are buried power rails is greater than the width WB1 of the power supply lines 11A and 12A of the cell 1 and also greater than the width WB2 of the power supply lines 11B and 12B of the cell 2 (WB3>WB1, WB3>WB2). The width WB3 is 40 nm, for example. Also, the width WN3 of nanosheets 21C and 22C is greater than the width WN1 of the nanosheets 21A and 22A of the cell 1 and also greater than the width WN2 of the nanosheets 21B and 22B of the cell 2 (WN3>WN1, WN3>WN2). The width WN3 is 36 nm, for example.

The layout structures of the 2-input NAND cells shown in FIGS. 4A, 4B, and 5 will be described. Note that description may be omitted here on configurations that can be inferred by analogy from the layout structures of the inverter cells shown in FIGS. 1A, 1B, 2, 3A, and 3B.

The 2-input NAND cell (cell 1) shown in FIG. 4A, like the inverter cell shown in FIG. 1A, has a cell height six times the pitch Pg of the virtual grid lines GL as described above. Power supply lines 13A and 14A extend in the X direction along both ends of the cell 1 in the Y direction. The power supply lines 13A and 14A are both buried power rails (BPRs) formed in the buried interconnect layer. The power supply line 13A supplies the power supply voltage VDD, and the power supply line 14A supplies the power supply voltage VSS. The center positions of the power supply lines 13A and 14A in the Y direction match with virtual grid lines GL. The width of the power supply lines 13A and 14A is WB1, which is the same as the width of the power supply lines 11A and 12A of the inverter cell (cell 1) shown in FIG. 1A.

P-type transistors P11 and P12 are formed on the N-well, and n-type transistors N11 and N12 are formed on the P-well or the p-type substrate. The transistors P11 and P12 have three nanosheets 23A and three nanosheets 24A, respectively, as channel regions. The transistors N11 and N12 have three nanosheets 25A and three nanosheets 26A, respectively, as channel regions. That is, the transistors P11, P12, N11, and N12 are nanosheet FETs. The width of the nanosheets 23A, 24A, 25A, and 26A is WN1, which is the same as the width of the nanosheets 21A and 22A of the inverter cell (cell 1) shown in FIG. 1A.

In the M1 interconnect layer, M1 interconnects 63A, 64A, and 65A extending in the X direction are formed. The M1 interconnect 63A, which corresponds to an input node A, is connected to a gate interconnect 32A, which is to be the gates of the transistors P11 and N11, through a contact. The M1 interconnect 64A, which corresponds to an input node B, is connected to a gate interconnect 33A, which is to be the gates of the transistors P12 and N12, through a contact. The M1 interconnect 65A, which corresponds to an output node Y, is connected to a local interconnect 44A connected to the drain of the transistor P11, and also connected to a local interconnect 45A connected to the drains of the transistors P12 and N12, through contacts. The M1 interconnects 63A, 64A, and 65A are all on virtual grid lines GL.

The 2-input NAND cell (cell 2) shown in FIG. 4B, like the inverter cell shown in FIG. 1B, has a cell height 7.5 times the pitch Pg of the virtual grid lines GL as described above.

The cell 2 shown in FIG. 4B has a layout structure similar to that of the cell 1 of FIG. 4A, except for the followings. The width WB2 of power supply lines 13B and 14B that are buried power rails is greater than the width WB1 of the power supply lines 13A and 14A of the cell 1 (WB2>WB1). Also, the width WN2 of nanosheets 23B, 24B, 25B, and 26B is greater than the width WN1 of the nanosheets 23A, 24A, 25A, and 26A of the cell 1 (WN2>WN1). Also, M1 interconnects 63B and 64B corresponding to input nodes A and B and an M1 interconnect 65B corresponding to an output node Y are all on virtual grid lines GL.

The 2-input NAND cell (cell 3) shown in FIG. 5, like the inverter cell shown in FIG. 2, has a cell height eight times the pitch Pg of the virtual grid lines GL as described above.

The cell 3 shown in FIG. 5 has a layout structure similar to that of the cell 1 of FIG. 4A, except for the followings. The width WB3 of power supply lines 13C and 14C that are buried power rails is greater than the width WB1 of the power supply lines 13A and 14A of the cell 1 and also greater than the width WB2 of the power supply lines 13B and 14B of the cell 2 (WB3>WB1, WB3>WB2). Also, the width WN3 of nanosheets 23C, 24C, 25C, and 26C is greater than the width WN1 of the nanosheets 23A, 24A, 25A, and 26A of the cell 1 and also greater than the width WN2 of the nanosheets 23B, 24B, 25B, and 26B of the cell 2 (WN3>WN1, WN3>WN2). Also, M1 interconnects 63C and 64C corresponding to input nodes A and B and an M1 interconnect 65C corresponding to an output node Y are all on virtual grid lines GL.

The cells 1, i.e., the inverter cell of FIG. 1A and the 2-input NAND cell of FIG. 4A, constitute a single circuit block together with other cells having the same cell height (=Pg×6). In this cell block, cells arranged in line in the X direction constitute a cell row, in which power supply lines supplying VDD, such as 11A and 13A, are coupled together, and power supply lines supplying VSS, such as 12A and 14A, are coupled together. Such cell rows are arranged side by side in the Y direction, with every other cell row inverted in the Y direction. With this arrangement, each cell row shares the power supply lines with its adjacent cell rows in the Y direction.

In the circuit block configured as described above, since the cell height of the cells 1 is an integral multiple of the pitch Pg of the virtual grid lines GL, both the upper and lower sides of the cell frame CF in the figure are on virtual grid lines GL for each cell 1. Also, the M1 interconnects that are to be the input and output nodes are on virtual grid lines GL for all the cells 1. Therefore, the width and spacing of the M1 interconnects can be kept regular.

Also, the cells 2, i.e., the inverter cell of FIG. 1B and the 2-input NAND cell of FIG. 4B, constitute a single circuit block together with other cells having the same cell height (=Pg×7.5). In this cell block, cells arranged in line in the X direction constitute a cell row, in which power supply lines supplying VDD, such as 11B and 13B, are coupled together, and power supply lines supplying VSS, such as 12B and 14B, are coupled together. Such cell rows are arranged side by side in the Y direction, with every other cell row inverted in the Y direction. With this arrangement, each cell row shares the power supply lines with its adjacent cell rows in the Y direction.

In the circuit block configured as described above, since the cell height of the cells 2 is (integer+0.5) times the pitch Pg of the virtual grid lines GL, the upper and lower sides of the cell frames CF in the figure are on virtual grid lines GL for each two cells 2 in the Y direction. Also, the M1 interconnects that are to be the input and output nodes are on virtual grid lines GL for both the normally placed cells and the invertedly placed cells. Therefore, the width and spacing of the M1 interconnects can be kept regular.

The cells 3, i.e., the inverter cell of FIG. 2 and the 2-input NAND cell of FIG. 5, constitute a single circuit block together with other cells having the same cell height (=Pg×8). In this cell block, cells arranged in line in the X direction constitute a cell row, in which power supply lines supplying VDD, such as 11C and 13C, are coupled together, and power supply lines supplying VSS, such as 12C and 14C, are coupled together. Such cell rows are arranged side by side in the Y direction, with every other cell row inverted in the Y direction. With this arrangement, each cell row shares the power supply lines with its adjacent cell rows in the Y direction.

In the circuit block configured as described above, since the cell height of the cells 3 is an integral multiple of the pitch Pg of the virtual grid lines GL, the upper and lower sides of the cell frame CF in the figure are on virtual grid lines GL for each cell 3. Also, the M1 interconnects that are to be the input and output nodes are on virtual grid lines GL for all the cells 3. Therefore, the width and spacing of the M1 interconnects can be kept regular.

In the layouts of the standard cells in this embodiment, as the cell height is greater in the order of cells 1, cells 2, and cells 3, the gate width of the nanosheets constituting the nanosheet FET, i.e., the transistor size, becomes greater (WN1<WN2<WN3). This increases the current flowing to the nanosheet FET, and therefore increases the current supply capability required for the power supply lines, in the order of cells 1, cells 2, and cells 3. In response to this, in this embodiment, the line width of the buried power rails is made greater in the order of cells 1, cells 2, and cells 3 (WB1<WB2<WB3), whereby the current supply capabilities required for these cells can be secured. Since the power supply lines having different line widths are buried power rails, the regularity of arrangement of interconnects in an interconnect layer located above the nanosheet FETs is not disturbed. For example, in this embodiment, all of the M1 interconnects that are to be the input and output nodes of the standard cells extend in the X direction in the M1 interconnect layer and are placed on virtual grid lines GL spaced at the equal pitch Pg in the Y direction.

Note that, in the layouts described above, the cells 1, the cells 2, and the cells 3 have the same number and size of contacts connecting the buried power rails and the local interconnects. However, at least the number or size of the contacts connecting the buried power rails and the local interconnects may be different among the cells 1, the cells 2, and the cells 3. For example, for buried power rails large in line width, the number of contacts may be increased, or the size of contacts may be increased. With this, since the resistance value of the power supply route becomes small, the current supply capability can be made greater.

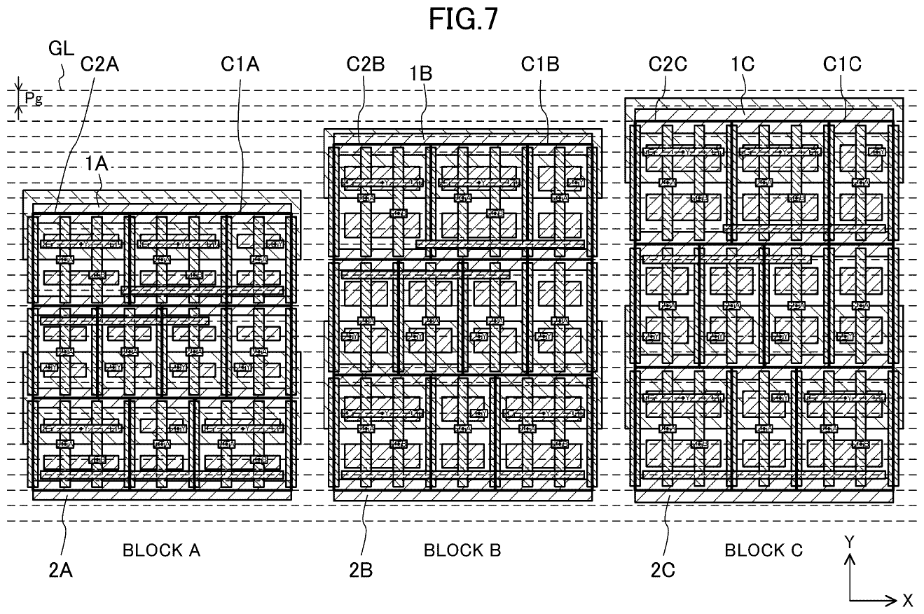

FIG. 7 shows a configuration example of circuit blocks of the semiconductor integrated circuit device of this embodiment. In FIG. 7, components other than the buried power rails, the nanosheet FETs, and the M1 interconnects are omitted. Also, in the M1 interconnect layer, only some of M1 interconnects are illustrated except for the M1 interconnects that are to be the input nodes and the output nodes.

In FIG. 7, a block A is constituted by the above-described cells 1, i.e., cells having a cell height of (Pg×6). A block B is constituted by the above-described cells 2, i.e., cells having a cell height of (Pg×7.5). A block C is constituted by the above-described cells 3, i.e., cells having a cell height of (Pg×8). The virtual grid lines GL are common to the blocks A, B, and C. The blocks A, B, and C are all formed of three cell rows.

In the block A, a cell C1A is the inverter cell of FIG. 1A, and a cell C2A is the 2-input NAND cell of FIG. 4A. In the first row from above, cells C2A, C2A, and C1A are arranged from the left in the figure. In the second row, cells C1A, C1A, C1A, and C1A are arranged from the left in the figure. In the third row, cells C2A, C1A, and C2A are arranged from the left in the figure. A power supply line 1A, supplying the power supply voltage VDD, is formed by coupling the power supply line 11A of the cell C1A and the power supply line 13A of the cell C2A together. A power supply line 2A, supplying the power supply voltage VSS, is formed by coupling the power supply line 12A of the cell C1A and the power supply line 14A of the cell C2A together.

In the block B, a cell C1B is the inverter cell of FIG. 1B, and a cell C2B is the 2-input NAND cell of FIG. 4B. In the first row from above, cells C2B, C2B, and C1B are arranged from the left in the figure. In the second row, cells C1B, C1B, C1B, and C1B are arranged from the left in the figure. In the third row, cells C2B, C1B, and C2B are arranged from the left in the figure. A power supply line 1B, supplying the power supply voltage VDD, is formed by coupling the power supply line 11B of the cell C1B and the power supply line 13B of the cell C2B together. A power supply line 2B, supplying the power supply voltage VSS, is formed by coupling the power supply line 12B of the cell C1B and the power supply line 14B of the cell C2B together.

In the block C, a cell C1C is the inverter cell of FIG. 2, and a cell C2C is the 2-input NAND cell of FIG. 5. In the first row from above, cells C2C, C2C, and C1C are arranged from the left in the figure. In the second row, cells C1C, C1C, C1C, and C1C are arranged from the left in the figure. In the third row, cells C2C, C1C, and C2C are arranged from the left in the figure. A power supply line 1C, supplying the power supply voltage VDD, is formed by coupling the power supply line 11C of the cell C1C and the power supply line 13C of the cell C2C together. A power supply line 2C, supplying the power supply voltage VSS, is formed by coupling the power supply line 12C of the cell C1C and the power supply line 14C of the cell C2C together.

In the blocks A and C, each standard cell is placed so that the upper and lower sides of the cell frame are located on virtual grid lines GL. In the block B, each standard cell is placed so that one of the upper and lower sides of the cell frame is located on a virtual grid line GL and the other is located on the center between adjacent virtual grid lines GL. Also, in the blocks A, B, and C, the M1 interconnects that are to be input and output nodes and other M1 interconnects are placed on virtual grid lines GL. With this placement, interconnects are regularly arranged in the M1 interconnect layer in the entire semiconductor integrated circuit device. This improves the manufacturing easiness, prevents manufacturing variations, and improves the yield, of the semiconductor integrated circuit device.

In addition, in the blocks A, B, and C, the widths of the buried power rails are greater in response to the gate widths of the nanosheet FETs of the standard cells in these blocks. With this, a sufficient current supply capability responsive to the power consumption of cells can be provided for each of the blocks A, B, and C. Moreover, since the power supply lines having different line widths are buried power rails, the regularity of arrangement of interconnects in an interconnect layer located above the nanosheet FETs is not disturbed.

As described above, according to this embodiment, a standard cell having a nanosheet FET greater in transistor size has a buried power rail greater in line width. Therefore, each standard cell can be provided with a sufficient current supply capability responsive to its power consumption. Also, since the power supply lines having different line widths are buried power rails, the regularity of arrangement of interconnects in an interconnect layer located above the nanosheets is not disturbed. In this embodiment, therefore, while the regularity of arrangement of interconnects in an interconnect layer located above transistors is maintained, each standard cell can be provided with a sufficient current supply capability responsive to its power consumption.

### Alteration

In this alteration, the relationship between the positions of the upper and lower sides of the cell frame CF of a standard cell and the positions of the virtual grid lines GL is different from that in the above-described embodiment. Note however that the positions of the M1 interconnects corresponding to the input and output nodes are changed with respect to the cell frame CF so as to be placed on virtual grid lines GL.

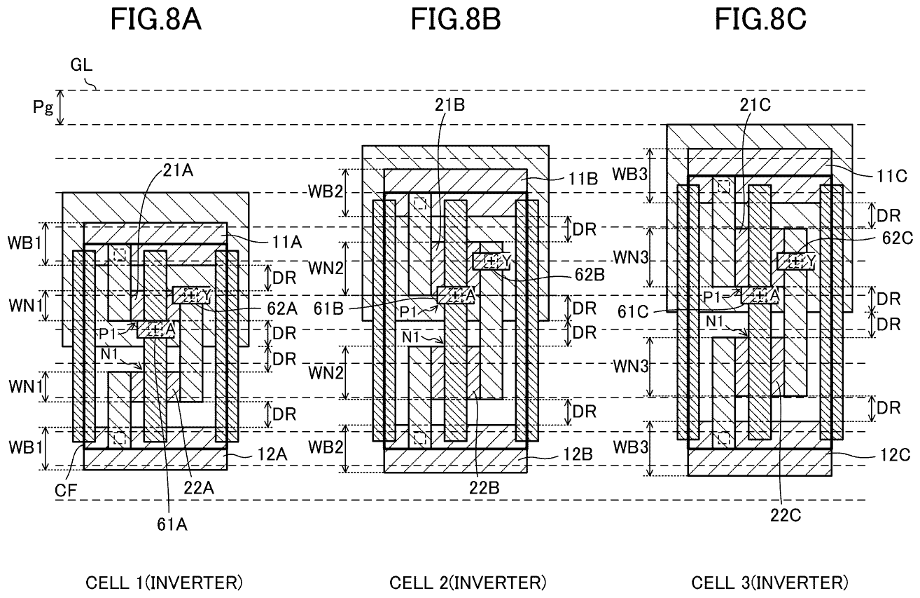

FIGS. 8A to 8C show layout structures of inverter cells according to the alteration. A cell 1 of FIG. 8A has substantially the same configuration as the cell 1 of FIG. 1A, except that the upper and lower sides of the cell frame CF are each located on the center between adjacent virtual grid lines GL. On the other hand, the M1 interconnect 61A corresponding to the input node A and the M1 interconnect 62A corresponding to the output node Y are located on virtual grid lines GL.

A cell 2 of FIG. 8B has substantially the same configuration as the cell 2 of FIG. 1B, except that the lower side of the cell frame CF is located on the center between adjacent virtual grid lines GL, and the upper side of the cell frame CF is located on a virtual grid line GL. On the other hand, the M1 interconnect 61B corresponding to the input node A and the M1 interconnect 62B corresponding to the output node Y are located on virtual grid lines GL.

A cell 3 of FIG. 8C has substantially the same configuration as the cell 3 of FIG. 2, except that the upper and lower sides of the cell frame CF are each located on the center between adjacent virtual grid lines GL. On the other hand, the M1 interconnect 61C corresponding to the input node A and the M1 interconnect 62C corresponding to the output node Y are located on virtual grid lines GL.

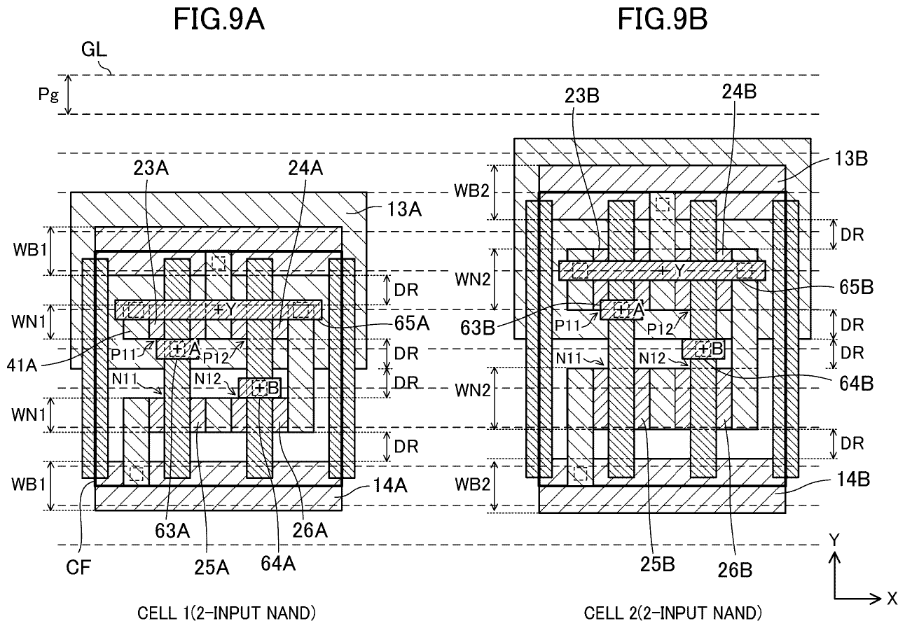

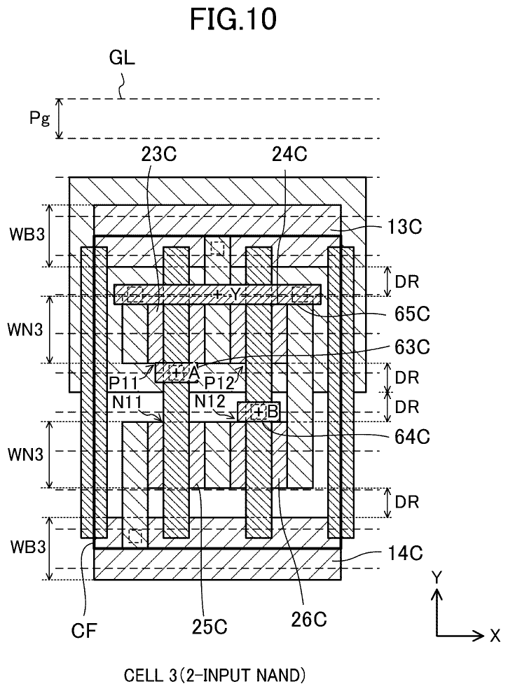

FIGS. 9A, 9B, and 10 show layout structures of 2-input NAND cells according to the alteration. A cell 1 of FIG. 9A has substantially the same configuration as the cell 1 of FIG. 4A, except that the upper and lower sides of the cell frame CF are each located on the center between adjacent virtual grid lines GL. On the other hand, the M1 interconnects 63A and 64A corresponding to the input nodes A and B and the M1 interconnect 65A corresponding to the output node Y are located on virtual grid lines GL.

A cell 2 of FIG. 9B has substantially the same configuration as the cell 2 of FIG. 4B, except that the lower side of the cell frame CF is located on the center between adjacent virtual grid lines GL, and the upper side of the cell frame CF is located on a virtual grid line GL. On the other hand, the M1 interconnects 63B and 64B corresponding to the input nodes A and B and the M1 interconnect 65B corresponding to the output node Y are located on virtual grid lines GL.

A cell 3 of FIG. 10 has substantially the same configuration as the cell 3 of FIG. 5, except that the upper and lower sides of the cell frame CF are each located on the center between adjacent virtual grid lines GL. On the other hand, the M1 interconnects 63C and 64C corresponding to the input nodes A and B and the M1 interconnect 65C corresponding to the output node Y are located on virtual grid lines GL.

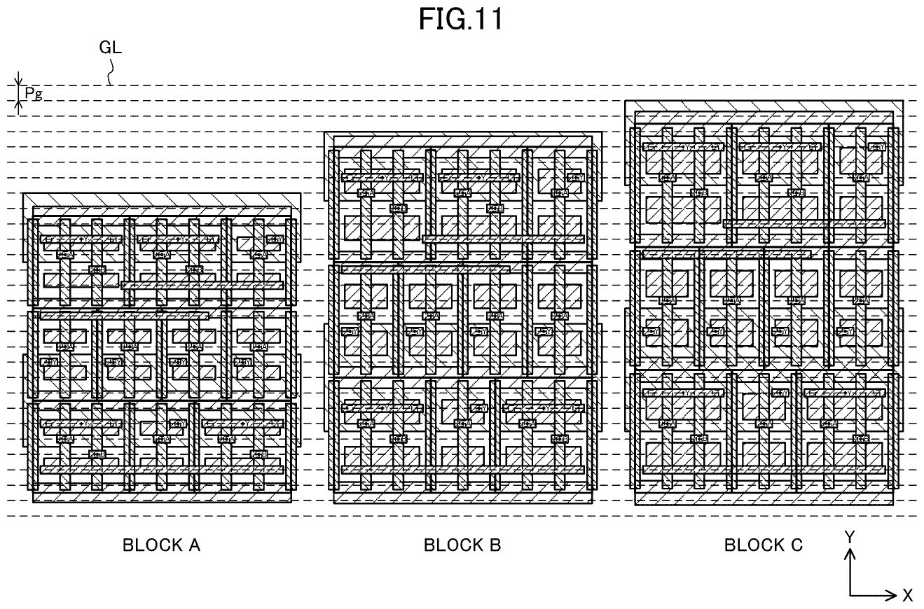

FIG. 11 shows a configuration example of circuit blocks of the semiconductor integrated circuit device of this alteration. The configuration of FIG. 11 is basically similar to that of FIG. 7, except that the correspondence relationship between the cell frames of the cells and the virtual grid lines GL is different from that of FIG. 7. On the other hand, the M1 interconnects corresponding to the input and output nodes of the cells and other M1 interconnects are located on virtual grid lines GL. With this placement, metal interconnects are regularly arranged in the M1 interconnect layer in the entire semiconductor integrated circuit device. This improves the manufacturing easiness, prevents manufacturing variations, and improves the yield, of the semiconductor integrated circuit device.

In addition, as in the above-described embodiment, in the blocks A, B, and C, the widths of the buried power rails are greater in response to the gate widths of the nanosheet FETs of the standard cells in these blocks. With this, a sufficient current supply capability responsive to the power consumption of cells can be provided for each of the blocks A, B, and C. Moreover, since the power supply lines having different line widths are buried power rails, the regularity of arrangement of interconnects in an interconnect layer located above the nanosheet FETs is not disturbed.

As described above, in this alteration, also, similar effects to those in the above-described embodiment are obtained. That is, a standard cell having a nanosheet FET greater in transistor size has a buried power rail greater in line width. Therefore, each standard cell can be provided with a sufficient current supply capability responsive to its power consumption. Also, since the power supply lines having different line widths are buried power rails, the regularity of arrangement of interconnects in an interconnect layer located above the nanosheets is not disturbed. In this alteration, therefore, while the regularity of arrangement of interconnects in an interconnect layer located above transistors is maintained, each standard cell can be provided with a sufficient current supply capability responsive to its power consumption.

Note that, while the virtual grid lines GL are grid lines in the M1 interconnect layer in the above description, they are not limited to these. For example, grid lines in a metal interconnect layer located above the M1 interconnect layer may be used as the virtual grid lines GL.

Also, while the metal interconnects corresponding to the input and output nodes of a standard cell are formed in the M1 interconnect layer in the above description, they may otherwise be formed in an interconnect layer located above the M1 interconnect layer.

Note that the cell heights of the cells 1, the cells 2, and the cells 3 illustrated in the above description are mere examples and are not limited to these.

According to the present disclosure, in a semiconductor integrated circuit device using buried power rails, while the regularity of arrangement of interconnects in an interconnect layer located above transistors is maintained, each standard cell can be provided with a sufficient current supply capability responsive to its power consumption. The present discloser is therefore useful for improving the degree of integration and performance of system LSI, for example.

1. A semiconductor integrated circuit device comprising a plurality of standard cells each having a nanosheet field effect transistor (FET),
wherein
in a first interconnect layer located above the nanosheet FETs, metal interconnects extend in a first direction and are placed on virtual grid lines spaced at an equal pitch in a second direction perpendicular to the first direction,
the plurality of standard cells includes
a first standard cell having a cell height corresponding to (0.5×N1) (N1 is a natural number) times the pitch of the virtual grid lines, and
a second standard cell having a cell height corresponding to (0.5×N2) (N2 is a natural number, N2>N1) times the pitch of the virtual grid lines,
the first standard cell includes
a first buried power rail extending in the first direction, and
a first nanosheet FET having a first nanosheet extending in the first direction, and
the second standard cell includes
a second buried power rail extending in the first direction and having a size in the second direction greater than the first buried power rail, and
a second nanosheet FET having a second nanosheet extending in the first direction and having a size in the second direction greater than the first nanosheet.

2. The semiconductor integrated circuit device of claim 1, wherein
the plurality of standard cells include
a third standard cell having a cell height corresponding to (0.5×N3) (N3 is a natural number, N3>N2) times the pitch of the virtual grid lines, and
the third standard cell includes
a third buried power rail extending in the first direction and having a size in the second direction greater than the second buried power rail, and
a third nanosheet FET having a third nanosheet extending in the first direction and having a size in the second direction greater than the second nanosheet.

3. The semiconductor integrated circuit device of claim 1, wherein the first and second standard cells achieve a same circuit function.

4. A semiconductor integrated circuit device comprising a plurality of standard cells each having a nanosheet field effect transistor (FET),
wherein
the plurality of standard cells includes a first standard cell and a second standard cell,
the first standard cell includes
a first buried power rail extending in a first direction, and
a first nanosheet FET having a first nanosheet extending in the first direction, and
the second standard cell includes
a second buried power rail extending in the first direction and having a size in a second direction greater than the first buried power rail, the second direction being perpendicular to the first direction, and
a second nanosheet FET having a second nanosheet extending in the first direction and having a size in the second direction greater than the first nanosheet.

5. The semiconductor integrated circuit device of claim 4, wherein
the plurality of standard cells include a third standard cell, and
the third standard cell includes
a third buried power rail extending in the first direction and having a size in the second direction greater than the second buried power rail, and
a third nanosheet FET having a third nanosheet extending in the first direction and having a size in the second direction greater than the second nanosheet.

6. The semiconductor integrated circuit device of claim 4, wherein
the first and second standard cells achieve a same circuit function.
